(19) United States
(12) Patent Application Publication
(10) Pub. No.: US 2011/0235259 A1
(43) Pub. Date: Sep. 29, 2011

(54) EXPANSION CARD ASSEMBLY AND HEAT SHIELDING COVER FOR EXPANSION CARD THEREOF

(75) Inventor: ZHENG-HENG SUN, Tu-Cheng (TW)

(73) Assignee: HON HAI PRECISION INDUSTRY CO., LTD., Tu-Cheng (TW)

(21) Appl. No.: 12/771,097

(22) Filed: Apr. 30, 2010

(30) Foreign Application Priority Data
Mar. 25, 2010 (CN) 201010132632.5

(51) Int. Cl. H05K 7/00

(52) U.S. Cl. 361/679.32

(57) ABSTRACT

An expansion card assembly includes an expansion card and a heat shielding cover. The expansion card is mounted to a chassis. The expansion card includes a printed circuit board (PCB) and a heat generating element. The heat shielding cover is fixed to the expansion card. The heat shielding cover includes a main cover mounted to the PCB and a breather cover mounted to the chassis. The breather cover defines at least one vent. The main cover insulates the heat generating element.

### BACKGROUND

1. Technical Field

The present disclosure relates to expansion card assemblies and heat shielding covers, and more particularly to an expansion card assembly and a cover to protect from the expansion card from heat.

2. Description of Related Art

Electronic elements in computers generate heat during normal operation, which can deteriorate their operational stability. Thus, the heat must be removed quickly to ensure normal operation. Some heat dissipation apparatus include a heat sink mounted on the electronic element to remove heat, and a fan fixed on the heat sink to generate airflow through the heat dissipation apparatus. With so many heat generating elements in the same computer enclosure, heat from one element may interfere with heat dissipation of another electronic element.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded, isometric view of an embodiment of a motherboard, a chassis and an expansion card assembly.

FIG. 2 is an exploded, isometric view of the expansion card assembly of FIG. 1.

FIG. 3 is similar to FIG. 2, but shows from another aspect.

FIG. 4 is an assembled view of the expansion card assembly and the motherboard of FIG. 1.

FIG. 5 is similar to FIG. 4, but shows in another aspect.

FIG. 6 is an assembled view of FIG. 1.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

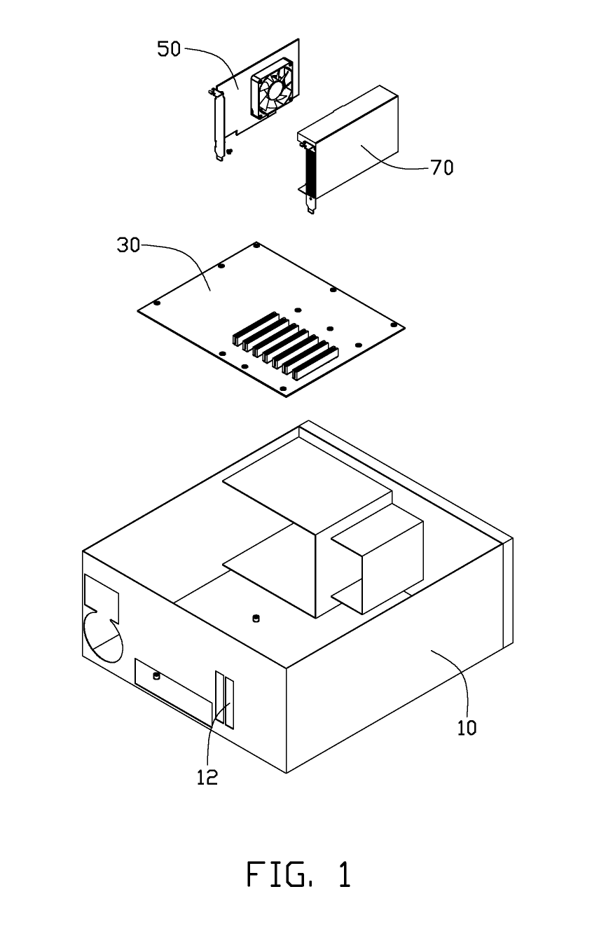

Referring to FIG. 1, an embodiment of an expansion card assembly is used to couple with a motherboard 30 in a chassis 10. The expansion card assembly includes an expansion card 50 and a heat shielding cover 70. The chassis 10 defines at least one slot 12.

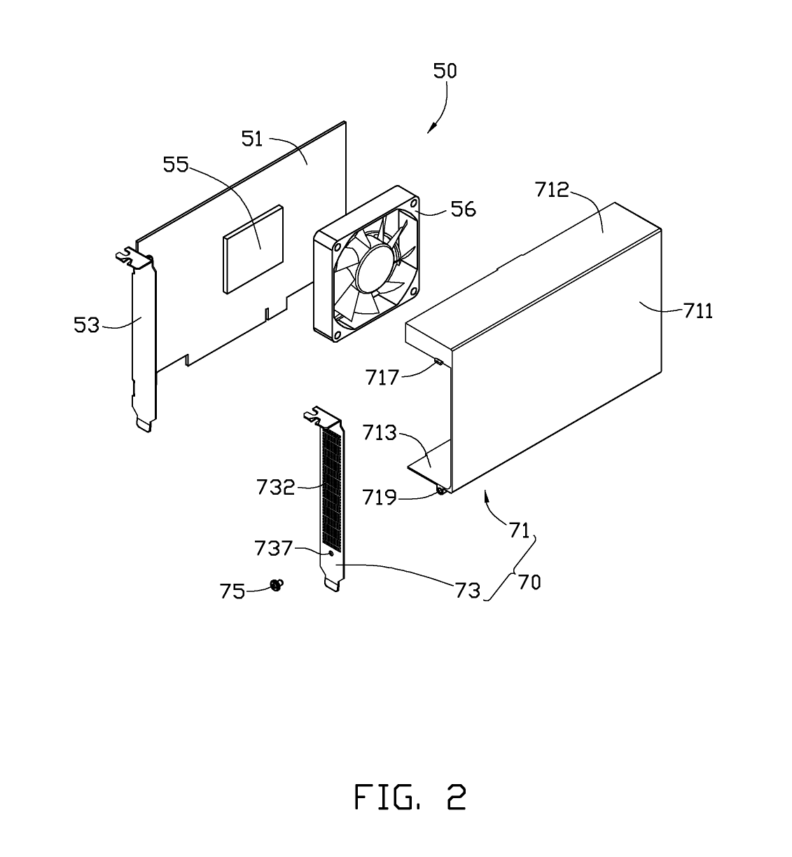

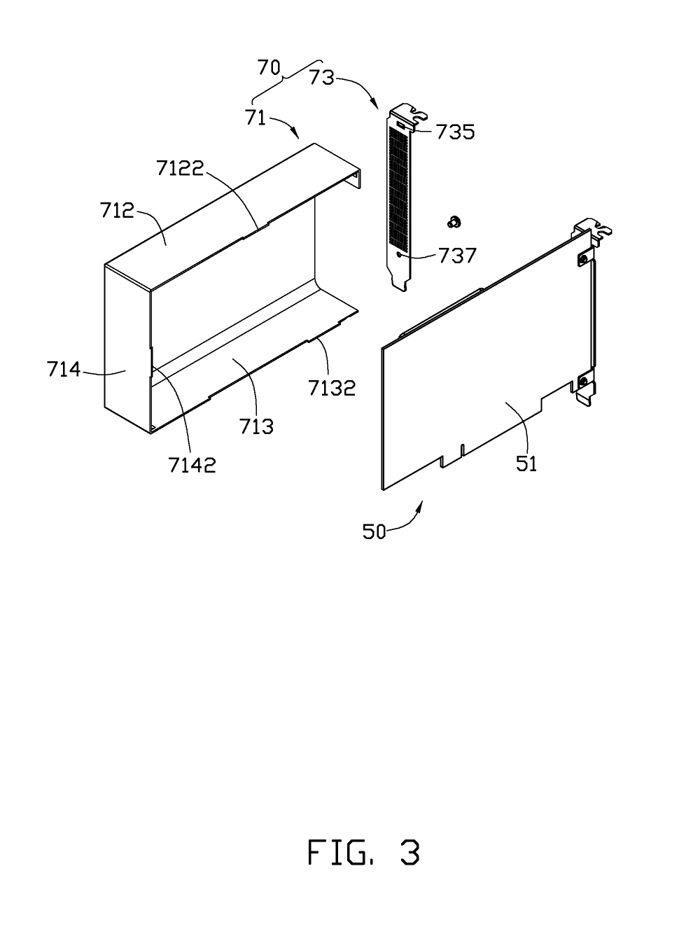

Referring through FIG. 2 and FIG. 3, the expansion card 50 includes a printed circuit board (PCB) 51 and a slot cover 53. The PCB 51 includes a heat generation element 55 and a heat dissipation apparatus 56 for removing heat from the heat generation element 55.

The heat shielding cover 70 includes a main cover 71 and a breather cover 73. The main cover 71 includes a sidewall 711, a top wall 712, a bottom wall 713 and a rear wall 714. The sidewall 711 can be parallel the PCB 51. The top wall 712, the bottom wall 713 and the rear wall 714 are perpendicular to the sidewall 711. A plurality of locking portions 7122, 7132, 7142 is formed on the top wall 712, the bottom wall 713, and the rear wall 714 respectively for fixing the main cover 71 to the PCB 51. The locking portions 7122, 7132, 7142 are hooked on three edges of the PCB 51 respectively. In one embodiment, at least two locking portions are needed to fix the main cover 71 to the PCB 51. A tab 717 protrudes from the top wall 712. A screw portion 719 is formed on the bottom wall 713. The screw portion 719 defines a screw hole. The breather cover 73 defines a plurality of vents 732, a locking hole 734 and a screw hole 737. The vents 732 include a plurality of parallel slots defined along a direction perpendicular to the sidewall 711.

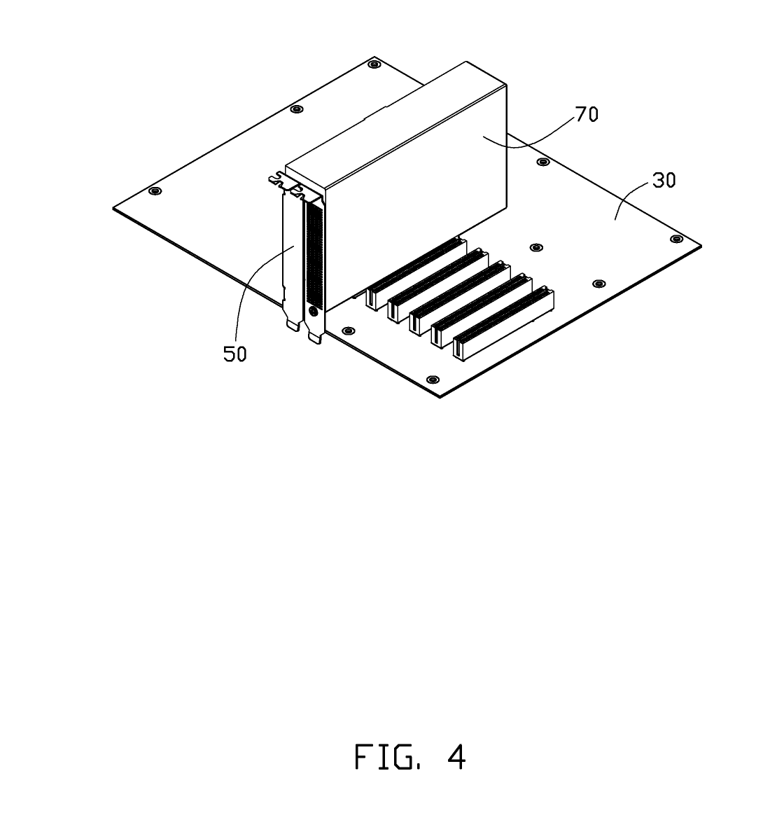

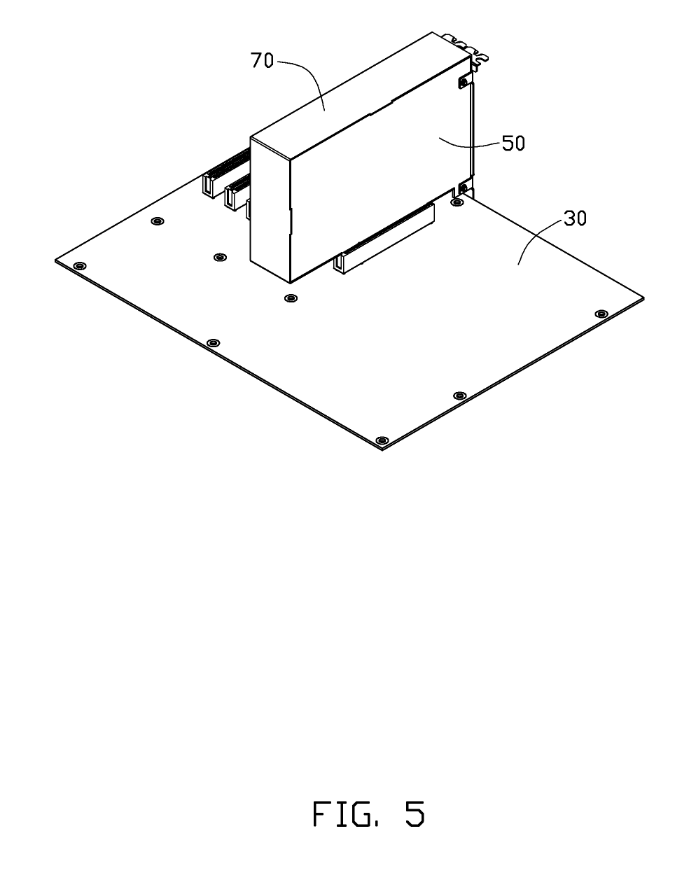

Referring to FIG. 4 and FIG. 5, to assemble the expansion card assembly, the breather cover 73 is fixed to the main cover 71. The tab 717 is engaged with the locking hole 737. A fastener 75 fastens the breather cover 73 to the main cover 71 through the screw hole 737. The main cover 71 is mounted to the edges of the PCB 51. The breather cover 73 is aligned with the slot cover 73. The heat shielding cover 70 encloses the heat generation element 55. The expansion card assembly is coupled to the motherboard 30.

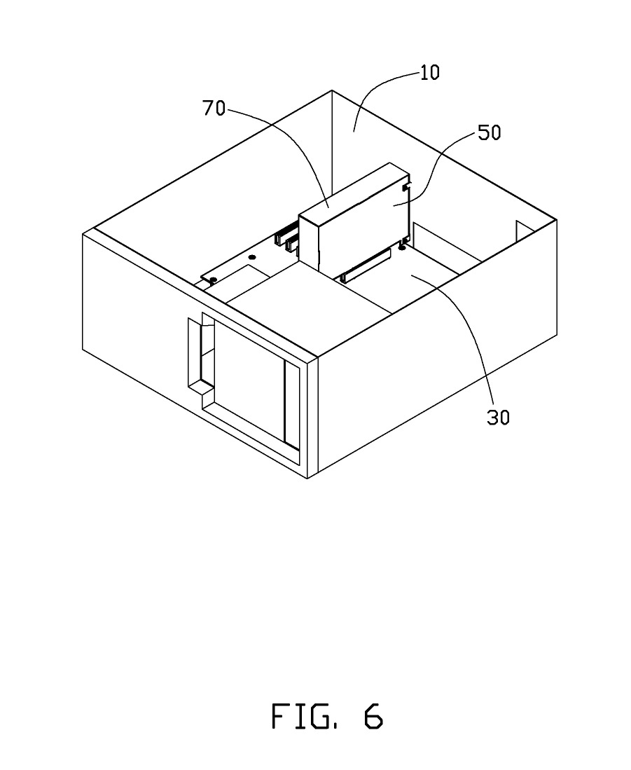

Referring to FIG. 6, the motherboard 30 is fixed to the chassis 10 with the slot cover 53 and the breather cover 73 covering the slots 12. When dissipating heat from the heat generation element 55, the heat dissipating apparatus 56 may generate airflow to remove heat through the vents 732. The heat generation element 55 is isolated by the heat shielding cover 70 from other heat generating elements (not shown) in the chassis 10. In this way, heat dissipation effect of the heat generating element 55 will not be affected by the other heat generating elements in the chassis 10.

It is also to be understood, however, that even though numerous characteristics and advantages have been set forth in the foregoing description of preferred embodiments, together with details of the structures and functions of the preferred embodiments, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. An expansion card assembly comprising:
an expansion card mounted to a chassis, the expansion card comprising a printed circuit board (PCB) and a heat generating element; and
a heat shielding cover fixed to the expansion card, the heat shielding cover comprising a main cover mounted to the PCB and a breather cover mounted to the chassis, and the breather cover defining at least one vent;
wherein the main cover insulate the heat generating element.

2. The expansion card assembly of claim 1, wherein the main cover comprises a sidewall, a top wall, a bottom wall and a rear wall; and the top wall, the bottom wall and the rear wall are perpendicular to the sidewall.

3. The expansion card assembly of claim 2, wherein the sidewall is parallel to the PCB.

4. The expansion card assembly of claim 2, further comprising locking portions for fixing the main cover to the PCB.

5. The expansion card assembly of claim 4, wherein each locking portion is hooked on an edge of the PCB.

6. The expansion card assembly of claim 2, wherein the breather cover is fixed to the main cover and is located parallel to the rear wall.

7. The expansion card assembly of claim 6, further comprising a tab that protrudes from the main cover, wherein a locking hole is defined in the breather cover for engaging with the tab.

8. The expansion card assembly of claim 6, wherein the main cover and the breather cover define screw holes for receiving a fastener.

9. The expansion card assembly of claim 6, wherein the at least one vent comprises a plurality of parallel slots defined along a direction perpendicular to the sidewall.

10. The expansion card assembly of claim 1, wherein the expansion card further comprises a heat dissipation apparatus attached to the heat generating element.

11. A heat shielding cover for an expansion card comprising:
a main cover mounted to a printed circuit board (PCB); and
a breather cover mounted to the main cover, and the breather cover defining at least one vent;
wherein the main cover encloses and insulates a heat generating element.

12. The heat shielding cover of claim 11, wherein the main cover comprises a sidewall, a top wall, a bottom wall and a rear wall; and the top wall, the bottom wall and the rear wall are perpendicular to the sidewall.

13. The heat shielding cover of claim 12, wherein the sidewall is parallel to the PCB.

14. The heat shielding cover of claim 12 further comprising locking portions for fixing the main cover to the PCB.

15. The heat shielding cover of claim 14, wherein each locking portion is hooked on an edge of the PCB.

16. The heat shielding cover of claim 12, wherein the breather cover is fixed to the main cover and is located parallel to the rear wall.

17. The heat shielding cover of claim 16 further comprising a tab protruding from the main cover, wherein a locking hole is defined in the breather cover for engaging with the tab.

18. The heat shielding cover of claim 16, wherein the main cover and the breather cover define screw holes for receiving a fastener.

19. The heat shielding cover of claim 16, wherein the at least one vent comprises a plurality of parallel slots defined along a direction perpendicular to the sidewall.
